(19) United States
(12) Patent Application Publication
(10) Pub. No.: US 2019/0312109 A1
(43) Pub. Date: Oct. 10, 2019

(54) FIELD-EFFECT TRANSISTORS WITH A COMPOSITE CHANNEL

(71) Applicant: GLOBALFOUNDRIES Inc., Grand Cayman (KY)

(72) Inventors: Heimanu Niebojewski, Cohoes, NY (US); Jagar Singh, Clifton Park, NY (US)

(21) Appl. No.: 15/946,281

(22) Filed: Apr. 5, 2018

(51) Int. Cl. H01L 29/10; H01L 29/08; H01L 29/165; H01L 27/12; H01L 29/78; H01L 21/02; H01L 29/66; H01L 21/308; H01L 21/324; H01L 21/84

(52) U.S. Cl. CPC H01L 29/1054; H01L 29/0847; H01L 29/165; H01L 27/1211; H01L 29/785; H01L 21/76283; H01L 29/66795; H01L 21/3081; H01L 21/324; H01L 21/845; H01L 21/0262; H01L 21/02532

(57) ABSTRACT

Device structures for a field-effect transistor and methods of forming a device structure for a field-effect transistor. A channel region is formed that includes first and second semiconductor layers, and a gate structure is formed that is arranged over the first and second semiconductor layers. First and second source/drain regions are formed in which the second source/drain region is separated from the first source/drain region by the channel region. The first semiconductor layer is composed of a semiconductor material having a first carrier mobility, and the second semiconductor layer is composed of a semiconductor material having a second carrier mobility that is greater than the first carrier mobility of the first semiconductor layer.

### BACKGROUND

The invention relates generally to integrated circuits and, in particular, to device structures for a field-effect transistor and methods of forming a device structure for a field-effect transistor.

Complementary-metal-oxide-semiconductor (CMOS) processes may be used to build a combination of p-type and n-type field-effect transistors (pFETs and nFETS) that are used to construct logic gates and as active components in other types of circuits, such as switches used in radiofrequency circuits. Field-effect transistors generally include an active semiconductor region, a source, a drain, and a gate electrode. When a control voltage exceeding a characteristic threshold voltage is applied to the gate electrode, carrier flow occurs in a channel between the source and drain to produce a device output current.

A semiconductor-on-insulator (SOI) substrate permits device operation at significantly higher speeds with improved electrical isolation and reduced electrical losses in comparison with field-effect transistors built using a bulk silicon wafer. Contingent on the thickness of the device layer of the SOI substrate, a field-effect transistor may operate in a fully-depleted mode in which a depletion layer in the channel extends fully to the buried oxide layer of the SOI substrate when typical control voltages are applied to the gate electrode.

Improved device structures for a field-effect transistor and methods of forming a device structure for a field-effect transistor are needed.

### SUMMARY

In an embodiment of the invention, a device structure is provided for a field-effect transistor. The device structure includes first and second source/drain regions, a channel region arranged laterally between the first and second source/drain regions, a gate structure arranged over the first semiconductor layer and the second semiconductor layer. The channel region includes a first semiconductor layer composed of a first semiconductor material having a first carrier mobility and a second semiconductor layer composed of a second semiconductor material having a second carrier mobility that is greater than the first carrier mobility of the first semiconductor layer.

In an embodiment of the invention, a method is provided for forming a device structure for a field-effect transistor. The method includes forming a first semiconductor layer and a second semiconductor layer defining a channel region, forming a gate structure arranged over the first semiconductor layer and the second semiconductor layer, and forming a first source/drain region and a second source/drain region separated from the first source/drain region by the channel region. The first semiconductor layer is composed of a first semiconductor material having a first carrier mobility and the second semiconductor layer is composed of a second semiconductor material having a second carrier mobility that is greater than the first carrier mobility of the first semiconductor layer.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention.

FIGS. 1-5 are cross-sectional views of a structure at successive fabrication stages of a process in accordance with embodiments of the invention.

FIG. 6 is a cross-sectional view similar to FIG. 5 of a structure in accordance with alternative embodiments of the invention.

### DETAILED DESCRIPTION

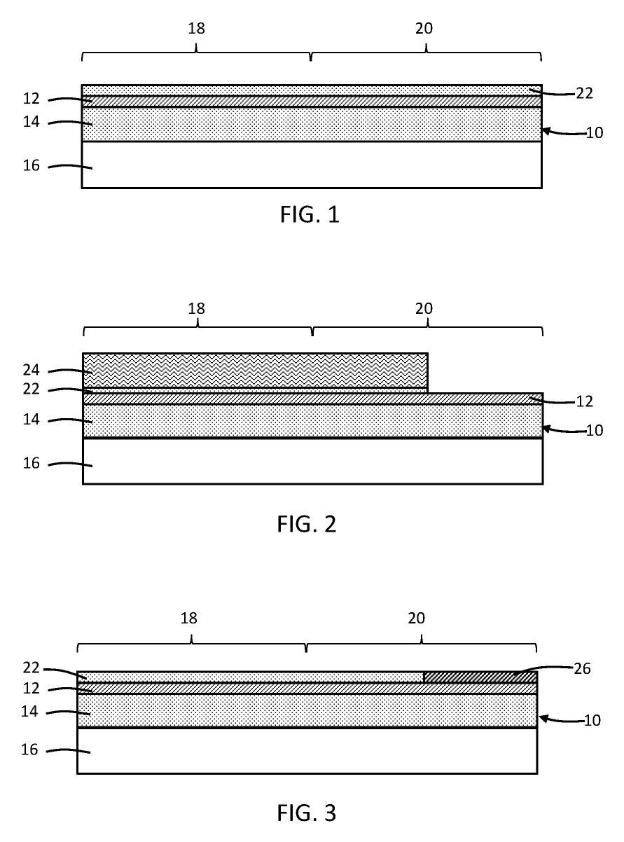

With reference to FIG. 1 and in accordance with an embodiment of the invention, a silicon-on-insulator (SOI) substrate 10 includes a buried dielectric layer in the form of a buried oxide (BOX) layer 14 composed of an oxide of silicon (e.g., SiO₂), and a substrate 16. The device layer 12 is separated from the substrate 16 by the intervening BOX layer 14 and may be considerably thinner than the substrate 16. The device layer 12 and the substrate 16 may be composed of a single-crystal semiconductor material, such as single-crystal silicon. In an embodiment, the device layer 12 may be extremely thin (i.e., a thickness of 2 nm to 15 nm) characteristic of extremely-thin silicon-on-insulator (ETSOI) substrate and may be used to construct fully-depleted SOI devices (FDSOI). The BOX layer 14 direct contacts the substrate 16 along an interface and directly contacts with the device layer 12 along another interface, and these interfaces are separated by the thickness of the BOX layer 14 and terminate at the outer rim of the SOI substrate 10. The device layer 12 is electrically isolated from the substrate 16 by the BOX layer 14. The substrate 16 may be lightly doped to have, for example, p-type conductivity.

The device layer 12 may be considered to include a device area 18 and a device area 20 that are eventually electrically isolated from each other. The different device areas 18, 20 will be used in the process flow to fabricate field-effect transistors characterized by different conductivity types. The device areas 18, 20 may be implanted to provide p-wells and n-wells (not shown) that may be needed for subsequent device formation.

A hardmask layer 22 is formed on a top surface of device layer 12. The material constituting the hardmask layer 22 may be chosen to etch selectively to the semiconductor material constituting the device layer 12 and configured to be readily removed at a subsequent fabrication stage. The hardmask layer 22 may be composed of a dielectric material, such as silicon dioxide (SiO₂), grown by oxidizing the top surface of device layer 12 or deposited by chemical vapor deposition (CVD) or atomic layer deposition (ALD).

With reference to FIG. 2 in which like reference numerals refer to like features in FIG. 1 and at a subsequent fabrication stage, the hardmask layer 22 is removed from a section of the device area 20 to expose the underlying device layer 12. To that end, an etch mask 24 is formed by lithography over the top surface of the device layer 12. The etch mask 24 completely covers the hardmask layer 22 in device area 18 and partially covers the hardmask layer 22 in device area 20. The etch mask 24 may be comprised of a layer of a photosensitive material, such as an organic photoresist, that may be applied as a fluid by a spin coating process, pre-baked, exposed to light projected through a photomask, baked after exposure, and developed with a chemical developer. The exposed portion of the hardmask layer 22 may be removed from the top surface of the device layer 12 in the section of device area 20 using an etching process, such as a wet chemical etching process or reactive ion etching (RIE), that removes the hardmask layer 22 selective to the device layer 12. As used herein, the term “selective” in reference to a material removal process (e.g., etching) denotes that, with an appropriate etchant choice, the material removal rate (i.e., etch rate) for the targeted material is greater than the removal rate for at least another material exposed to the material removal process. The hardmask layer 22 in device area 18 and the masked portion of the hardmask layer 22 in device area 20 are protected by the etch mask 24 during the etching process. The etch mask 24 is stripped following the completion of the etching process.

With reference to FIG. 3 in which like reference numerals refer to like features in FIG. 2 and at a subsequent fabrication stage, an epitaxial semiconductor layer 26 is formed over the top surface of the device layer 12 across the exposed section of the device layer 12 in device area 20. The epitaxial semiconductor layer 26 may be in direct contact with the exposed section of the device layer 12, which provides the crystal structure serving as a template for epitaxial growth. In an embodiment, the epitaxial semiconductor layer 26 may contain germanium (Ge) and, in particular, the epitaxial semiconductor layer 26 may be composed of silicon-germanium (SiGe) deposited by chemical vapor deposition (CVD) and having a germanium concentration (i.e., the ratio of the germanium content to the germanium and silicon content) ranging from 2% to 50%. The epitaxial semiconductor layer 26 may be formed using an epitaxial growth process, such as a selective epitaxial growth process in which the constituent semiconductor material nucleates for epitaxial growth from semiconductor surfaces, but does not nucleate for epitaxial growth from insulator surfaces (e.g., the top surface of the hardmask layer 22).

With reference to FIG. 4 in which like reference numerals refer to like features in FIG. 3 and at a subsequent fabrication stage, a section of the device layer 12 in the device area 20 that nominally coincides with the area covered by the epitaxial semiconductor layer 26 (FIG. 3) is modified in its composition using a thermal process to form a semiconductor layer 28. The semiconductor layer 28 may extend from the top surface of the device layer 12 to the BOX layer 14 and may be in direct contact with the BOX layer 14. In that regard, the entire thickness of the device layer 12 may be locally modified by the thermal process beneath the epitaxial semiconductor layer 26 to form the semiconductor layer 28. The semiconductor layer 28 in device area 20 has a different composition than the adjacent section of the device layer 12 in device areas 18 and 20. The semiconductor layer 28 adjoins the device layer 12 in device area 20 along a vertical interface 29 that is nominally aligned with the mask edge, and the semiconductor layer 28 is composed of a semiconductor material having a higher carrier mobility (e.g., hole mobility) than the semiconductor material of the device layer 12.

In an embodiment, the thermal process may be thermal condensation that causes germanium atoms to be transported (e.g., diffuse) from the epitaxial semiconductor layer 26 into the exposed section of the device layer 12. Thermal condensation may be performed using a rapid thermal oxidation process with the SOI substrate 10 held in an ambient atmosphere having an oxygen content. During oxidation, the epitaxial semiconductor layer 26 oxidizes across its thickness beginning at its top surface and advancing toward the interface with the underlying section of the device layer 12. Germanium atoms are irreversibly transported from the epitaxial semiconductor layer 26 into the section of the device layer 12 as oxidation proceeds. Thermal condensation is based upon, among other factors, germanium and silicon each having diamond lattice structures and the different chemical affinities between germanium and silicon with respect to oxygen. The BOX layer 14 rejects the diffusion of germanium such that the germanium displaced from the epitaxial semiconductor layer 26 is located entirely (i.e., confined) in the modified semiconductor layer 28 that is enriched in germanium.

The hardmask layer 22, which is oxygen impermeable, protects the unmodified semiconductor layer 30 during the performance of the thermal condensation process. The end result of thermal condensation is that the epitaxial semiconductor layer 26 is converted to an oxidized remnant layer 32 that is depleted of germanium (e.g., silicon dioxide (SiO₂)), and the section of the device layer 12 receiving the germanium is converted to the germanium-enriched semiconductor material (e.g., silicon-germanium (SiGe)) of the semiconductor layer 28. The germanium concentration in the semiconductor layer 28 depends on, among other factors, the thickness and composition of the device layer 12, and the germanium content and thickness of the epitaxial semiconductor layer 26. Following the thermal process, the oxidized remnant layer 32, which has a composition that is depleted of germanium by the thermal process, may be removed, such as by etching, for example, using a dilute hydrofluoric acid (HF).

The semiconductor layer 28 may incorporate compressive strain due to a change to its crystal structure induced by the incorporated germanium atoms, which may be effective to alter carrier mobility. Germanium atoms, which are located at lattice sites in the crystal structure of the semiconductor material of the semiconductor layer 28, have a larger atomic size than, for example, silicon atoms. Generally, the lattice constant of silicon-germanium is slightly larger than the lattice constant of silicon.

With reference to FIG. 5 in which like reference numerals refer to like features in FIG. 4 and at a subsequent fabrication stage, the hardmask layer 22 is stripped, and trench isolation regions 34 are formed that penetrate through the device layer 12 and the BOX layer 14, and extend to a given depth into the substrate 16. The trench isolation regions 34 surround the device layer 12 in each of the device areas 18, 20, and electrically isolate the section of the device layer 12 in device area 18 from the section of the device layer 12 in device area 20. In particular, the trench isolation regions 34 surround the semiconductor layer 28 with modified composition and a section of the unmodified device layer 12 defining a semiconductor layer 30. The semiconductor layer 30 adjoins the semiconductor layer 28 at the vertical interface 29 within the device area 20. The semiconductor material of the semiconductor layer 28 is characterized by a higher carrier mobility than the semiconductor material of the semiconductor layer 30 originating from the section of the device layer 12 that is masked during the thermal process forming the semiconductor layer 28.

Trench isolation regions 34 may be formed by a shallow trench isolation (STI) technique in which trenches are formed and then filled with an electrical insulator by depositing a layer of the electrical insulator and then polishing and/or recessing the deposited layer. The trench isolation region 34 may be comprised of one or more dielectric materials, such as an oxide of silicon (e.g., silicon dioxide (SiO₂)) and/or a nitride of silicon (e.g., silicon nitride (Si₃N₄)), deposited by chemical vapor deposition (CVD) or atomic layer deposition (ALD).

A device structure 40 for a field-effect transistor is formed by front-end-of-line (FEOL) processing in the device area 18, and a device structure 42 for a field-effect transistor is formed by FEOL processing in the device area 20. To that end, a dielectric layer and one or more conductor layers may be deposited and patterned to form a gate dielectric 44 and gate electrode 46 of a gate structure associated with the device structure 40 and to form a gate dielectric 45 and gate electrode 47 of a gate structure associated with the device structure 42. The gate structures may be functional gate structures in which the gate dielectrics 44, 45 are a high-k dielectric material like hafnium oxide (HfO₂), and the gate electrodes 46, 47 include one or more conformal barrier metal layers and/or work function metal layers, such as layers composed of titanium aluminum carbide (TiAlC) and/or titanium nitride (TiN), and a metal gate fill layer composed of a conductor, such as tungsten (W).

Alternatively, in a “gate last” integration scheme, the gate structures may be sacrificial gate structures that are composed of polysilicon and that serve as placeholders for functional gate structures in a replacement metal gate process. Alternatively, the gate structures may include a gate dielectric, a gate electrode (e.g., titanium nitride), and polysilicon as a gate stack in a “gate first” integration scheme.

Spacers 48 may be formed on the vertical sidewalls of the gate structures of the device structures 40, 42. The spacers 48 may be comprised of a nitride-based dielectric material, such as SiOCN, SiBCN, SiN, etc., that is deposited and etched with reactive ion etching (RIE).

Source/drain regions 50 are formed adjacent to the vertical sidewalls of the gate structure of the device structure 40 and are separated from the gate structure by the spacers 48. Source/drain regions 51, 52 are formed adjacent to the vertical sidewalls of the gate structure of the device structure 42 and are separated from the gate structures by the spacers 48. As used herein, the term “source/drain region” means a doped region of semiconductor material that can function as either a source or a drain of a field-effect transistor. In an embodiment, the device structure 40 may be an n-type field-effect transistor and the device structure 42 may be a p-type field-effect transistor. The source/drain regions 50 may be composed of a semiconductor material, such as silicon (Si), formed by an epitaxial growth process, and may be in situ doped during growth to impart a given conductivity type (e.g., n-type conductivity for an n-type field-effect transistor) to the grown semiconductor material. The source/drain regions 51, 52 are composed of a semiconductor material, such as silicon germanium (SiGe), formed by an epitaxial growth process, and may be in situ doped during growth to impart a given conductivity type (e.g., a p-type conductivity for a p-type field-effect transistor) to the grown semiconductor material.

The device structure 42 has a composite channel region 54 that includes the semiconductor layer 28 and the semiconductor layer 30 as adjoining sections. The composite channel region 54 is arranged beneath the gate structure including the gate dielectric 45 and gate electrode 47, and the composite channel region 54 is arranged laterally between the source/drain region 51 and the source/drain region 52. In the representative embodiment, the source/drain regions 51, 52 are raised relative to the composite channel region 54. In that regard, the source/drain region 51 of the device structure 42 is arranged over the semiconductor layer 30, the source/drain region 52 is arranged over the semiconductor layer 28, and the source/drain region 51 is separated from the source/drain region 52 by the composite channel region 54.

In an embodiment, the source/drain region 51 arranged over the semiconductor layer 30 may be a drain of the device structure 42 and the source/drain region 52 arranged over the semiconductor layer 28 may be a source of the device structure 42. Placing the semiconductor layer 30, which is an unmodified section of the device layer 12, on the drain-side of the device structure 42 may reduce gate-induced drain leakage (GIDL) during operation at the positive supply voltage (V_{DD}). Placing the modified semiconductor layer 28 on the source-side of the device structure 42 may improve device performance (e.g., Iₒₙ) and reliability (e.g., reduce negative-bias temperature instability (NBTI) degradation) during operation. Due to its modification by the thermal process, the semiconductor layer 28 may exhibit a higher carrier mobility (e.g., hole mobility) than the semiconductor layer 30 during device operation.

The semiconductor layer 28 has a width, w1, the semiconductor layer 30 has a width, w2, and the composite channel region 54 has a total width that is equal to the sum of these individual widths. The ratio of these widths may be varied to tune the performance of the device structure 42. To that end, a value for the ratio may be established when the hardmask layer 22 is patterned before the formation of the epitaxial semiconductor layer 26. In an embodiment, the ratio may be selected such that the semiconductor layer 28 has a greater width than the semiconductor layer 30 and, therefore, constitutes the majority of the composite channel region 54. The widths of the semiconductor layers 28, 30 and composite channel region 54 may be measured in a direction from the source/drain region 51 toward the source/drain region 52.

Middle-of-line (MOL) processing and back-end-of-line (BEOL) processing follows the fabrication of the device structures 40, 42, which includes formation of dielectric layers, via contacts, and wiring for an interconnect structure coupled with the device structures 40, 42.

In an embodiment, the device structures 40, 42 may be used as input-output transistors in an integrated circuit. In an alternative embodiment, the device structures 40, 42 may be fabricated as using a bulk semiconductor substrate instead of the SOI substrate 10.

In an embodiment, the device structure 42 may be a zero-threshold-voltage field-effect transistor (or natural transistor) that is commonly used in low-voltage operational amplifier, analog, digital, and mixed-signal circuits, and low-power and interface circuits. In contrast with conventional process flows, the zero-threshold-voltage field-effect transistor may be have the construction of the device structure 42, which is fabricated without an additional mask that is needed in conventional process flows to form an additional well in the channel that can be biased to adjust the threshold voltage to equal zero volts.

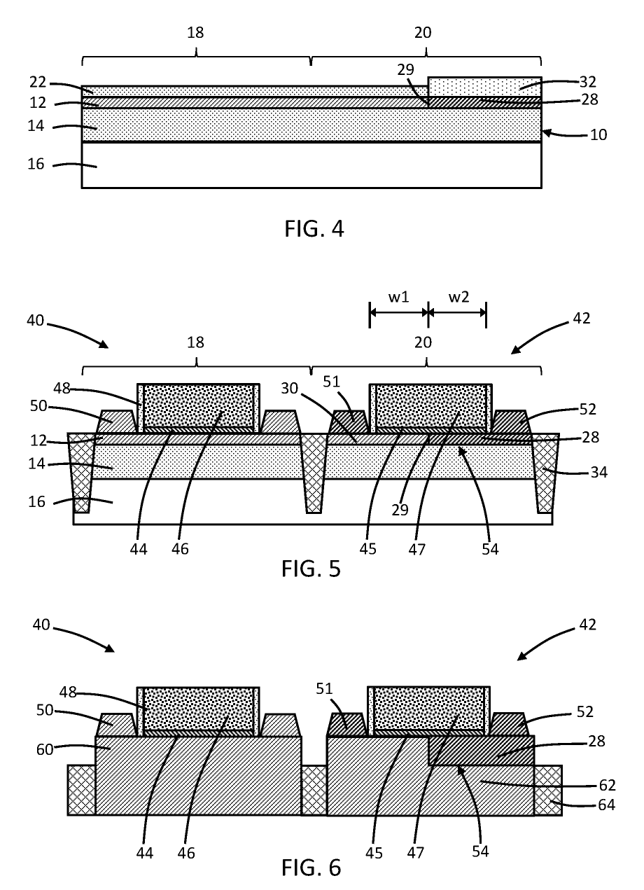

With reference to FIG. 6 in which like reference numerals refer to like features in FIG. 5 and in accordance with alternative embodiments of the invention, the device structures 40, 42 may be fin-type field-effect transistors formed using fins 60, 62. The fins 60, 62 may be patterned from a layer of semiconductor material using a multiple patterning process, such as self-aligned double patterning (SADP), and cut into given lengths in the layout. Trench isolation 64 may be formed that surrounds lower portions of the fins 60, 62 by depositing a dielectric layer, which may be composed of silicon dioxide (SiO₂), and recessing the deposited dielectric layer with an etching process. Processing continues to form a gate structure and source/drain regions 50 associated with the device structure 40, and to form a gate structure and source/drain regions 51, 52 associated with the device structure 42.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

References herein to terms such as “vertical”, “horizontal”, “lateral”, etc. are made by way of example, and not by way of limitation, to establish a frame of reference. Terms such as “horizontal” and “lateral” refer to a directions in a plane parallel to a top surface of a semiconductor substrate, regardless of its actual three-dimensional spatial orientation. Terms such as “vertical” and “normal” refer to a direction perpendicular to the “horizontal” direction. Terms such as “above” and “below” indicate positioning of elements or structures relative to each other and/or to the top surface of the semiconductor substrate as opposed to relative elevation.

A feature “connected” or “coupled” to or with another element may be directly connected or coupled to the other element or, instead, one or more intervening elements may be present. A feature may be “directly connected” or “directly coupled” to another element if intervening elements are absent. A feature may be “indirectly connected” or “indirectly coupled” to another element if at least one intervening element is present.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A device structure for a field-effect transistor, the device structure comprising:
a first source/drain region;
a second source/drain region;
a channel region arranged laterally between the first source/drain region and the second source/drain region, the channel region including a first semiconductor layer comprised of a first semiconductor material having a first carrier mobility and a second semiconductor layer comprised of a second semiconductor material having a second carrier mobility that is greater than the first carrier mobility of the first semiconductor layer; and
a gate structure arranged over the first semiconductor layer and the second semiconductor layer,
wherein the first semiconductor layer of the channel region and the second semiconductor layer of the channel region are each arranged in direct contact with a buried oxide layer of a silicon-on-insulator substrate.

2. (canceled)

3. The device structure of claim 1 wherein the first semiconductor layer is a first section of a device layer of the silicon-on-insulator substrate, and the second semiconductor layer is a second section of the device layer that is modified to provide the second semiconductor material.

4. (canceled)

5. The device structure of claim 1 wherein the channel region is located in a semiconductor fin.

6. The device structure of claim 1 wherein the first source/drain region and the second source/drain region are composed comprised of silicon-germanium.

7. The device structure of claim 1 wherein the first source/drain region and the second source/drain region are comprised of a p-type semiconductor material.

8. The device structure of claim 1 wherein the first semiconductor material is single-crystal silicon, and the second semiconductor material is single-crystal silicon-germanium.

9. The device structure of claim 1 wherein the gate structure is arranged laterally between the first source/drain region and the second source/drain region, the first source/drain region is arranged over the first semiconductor layer, and the second source/drain region is arranged over the second semiconductor layer.

10. The device structure of claim 9 wherein the first source/drain region is a drain of the field-effect transistor, and the second source/drain region is a source of the field-effect transistor.

11. A method of forming a device structure for a field-effect transistor, the method comprising:
forming a first semiconductor layer and a second semiconductor layer defining a channel region;
forming a gate structure arranged over the first semiconductor layer and the second semiconductor layer; and
forming a first source/drain region and a second source/drain region separated from the first source/drain region by the channel region,
wherein the first semiconductor layer is comprised of a first semiconductor material having a first carrier mobility, [[and]] the second semiconductor layer is comprised of a second semiconductor material having a second carrier mobility that is greater than the first carrier mobility of the first semiconductor layer, and the first semiconductor layer of the channel region and the second semiconductor layer of the channel region are each arranged in direct contact with a buried oxide layer of a silicon-on-insulator substrate.

12. The method of claim 11 wherein the first semiconductor material is silicon, and the second semiconductor material is silicon-germanium.

13. The method of claim 11 wherein forming the channel region having the first semiconductor layer and the second semiconductor layer comprises:
forming a hardmask layer over a device layer of a silicon-on-insulator substrate;
patterning the hardmask layer to expose a portion of the device layer;
depositing an epitaxial semiconductor layer on the portion of the device layer; and
transporting atoms of an element from the epitaxial semiconductor layer into the exposed portion of the device layer to form the second semiconductor layer of the channel region.

14. The method of claim 13 wherein the epitaxial semiconductor layer is composed of silicon-germanium, and transporting the atoms of the element from the epitaxial semiconductor layer into the exposed portion of the device layer comprises:
performing a thermal process to transport germanium atoms from the epitaxial semiconductor layer into the device layer to form the first semiconductor layer of the channel region.

15. The method of claim 14 wherein the thermal process is thermal condensation in which the silicon-germanium of the epitaxial semiconductor layer is converted into an oxide of silicon by thermal oxidation as germanium is transported from the epitaxial semiconductor layer into the device layer.

16. (canceled)

17. The method of claim 11 wherein the first semiconductor material is single-crystal silicon, and the second semiconductor material is single-crystal silicon-germanium.

18. The method of claim 11 wherein the first semiconductor layer is a first section of a device layer of a silicon-on-insulator substrate, and the second semiconductor layer is a second section of the device layer that is modified to provide the second semiconductor material.

19. The method of claim 11 wherein the channel region is located in a semiconductor fin.

20. (canceled)

21. The structure of claim 1 further comprising:
a plurality of shallow trench isolation regions arranged to surround the channel region,
wherein the first semiconductor layer has a first width, and the second semiconductor layer has a second width, the channel region has a third width equal to a sum of the first width and the second width, and the second width is greater than the first width.

22. The method of claim 11 further comprising:
forming a plurality of shallow trench isolation regions arranged to surround the channel region,
wherein the first semiconductor layer has a first width, and the second semiconductor layer has a second width, the channel region has a third width equal to a sum of the first width and the second width, and the second width is greater than the first width.
